(19) United States
(12) Patent Application Publication
(10) Pub. No.: US 2025/0030445 A1
(43) Pub. Date: Jan. 23, 2025

(54) POWER COMBINER/DIVIDER WITH BROADBAND ISOLATION

(71) Applicant: Apple Inc., Cupertino, CA (US)

(72) Inventors: Tarek Khedr Abdalla Mealy, San Diego, CA (US); Abbas Komijani, Mountain View, CA (US); Zhengan Yang, Del Mar, CA (US); Reetika K Agarwal, San Jose, CA (US); Hongrui Wang, San Jose, CA (US); Zhang Jin, San Diego, CA (US)

(21) Appl. No.: 18/356,956

(22) Filed: Jul. 21, 2023

(51) Int. Cl. H04B 1/04; H03F 1/56; H03F 3/21

(52) U.S. Cl. CPC H04B 1/0483; H03F 1/565; H03F 3/21; H04B 1/0475; H03F 2200/294; H03F 2200/451

(57) ABSTRACT

This disclosure is directed to a power combiner/divider with improved operating frequency range (e.g., bandwidth) compared to other power combiners/dividers. The power combiner/divider may include an isolation circuit including a first resonant circuit and a second resonant circuit coupled to terminals (e.g., input terminals, output terminals) of the power combiner/divider. The first resonant circuit may attenuate signals having frequencies in a first frequency range below an attenuation threshold between the terminals of the power combiner/divider. The second resonant circuit may attenuate signals having frequencies in a second frequency range below an attenuation threshold between the terminals of the power combiner/divider. Accordingly, the isolation circuit may improve isolation between multiple terminals of the power combiner/divider at a wider bandwidth compared to other power combiners/dividers based attenuating cross-talk between the terminal at the first frequency range and the second frequency range.

### BACKGROUND

The present disclosure relates generally to wireless communication, and more specifically to power combiners and/or dividers of transmitter and/or receiver circuits.

In some applications, such as high frequency (e.g., millimeter wave (mmWave)) applications, an electronic device may transmit and/or receive radio frequency (RF) signals across a frequency bandwidth (referred to herein as a “device bandwidth”). The electronic device may include multiple data communication chains coupled to one or more antennas to transmit and/or receive the signals. A frequency bandwidth of each of the data communication chains for transmitting and/or receiving the signals may correspond to a portion of the device bandwidth of the electronic device. For example, each data communication chain may couple to at least one antenna associated with the respective bandwidth of the data communication chain.

One or more data communication chains may include a power combiner/divider to combine and/or divide signals. A power combiner/divider may combine multiple input signals to generate one output signal. Alternatively or additionally, the power combiner/divider may divide one input signal to generate multiple output signals. For example, two data communication chains may share a power combiner/divider to combine and/or divide signals having frequencies in different bandwidths. Alternatively, a single data communication chain may include a power combiner/divider to combine and/or divide signals.

A bandwidth of a data communication chain for transmitting and/or receiving the signals may be at least partly based on a bandwidth of the respective power combiner/divider. The power combiner/divider may have reduced, impaired, or limited bandwidth for combining and/or dividing signals. For example, leakage between terminals (e.g., ports) of the power combiner/divider may cause cross-talk or interference of signals between the terminals when combining and/or dividing signals. The cross-talk or interference of signals between the terminals of the power combiner/divider may limit the bandwidth of the data communication chain. In turn, the limited bandwidth of the data communication chain may correspond to a smaller portion of the device bandwidth of the electronic device. If not compensated for, the electronic device may include an increased number of the data communication chains and/or the power combiners/dividers to transmit or receive the signals in the device bandwidth to compensate for the limited bandwidth. The increased number of the data communication chains and/or the power combiners/dividers may occupy an increased circuit area. Such increases in a circuit area of the electronic device may be undesired.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a power combiner/divider includes a first capacitor, a first resistor coupled in parallel to the first capacitor, a first inductor coupled to the first capacitor and the first resistor, and a second inductor coupled to the first capacitor, the first resistor, and the first inductor forming a first loop. The power combiner/divider also includes a second capacitor, a third inductor coupled to the second capacitor, and a fourth inductor coupled to the second capacitor and the third inductor forming a second loop, the second loop being disposed within or around the first loop.

In another embodiment, a power combiner/divider includes a first resonant circuit configured to attenuate signals having a frequency in a first frequency range between a first terminal and a second terminal, the first resonant circuit comprising a first inductor coupled to the first terminal and a third terminal and a second inductor coupled to the second terminal and the third terminal. The power combiner/divider also includes a second resonant circuit configured to attenuate signals having a frequency in a second frequency range between the first terminal and the second terminal, the second resonant circuit comprising a third inductor configured to inductively couple to the first inductor and a fourth inductor configured to inductively couple to the second inductor.

In yet another embodiment, an electronic device includes one or more antennas and a power combiner/divider coupled to the one or more antennas. The power combiner/divider is configured to receive signals from or provide the signals to the one or more antennas having a frequency in a bandwidth. The power combiner/divider includes a first resonant circuit configured to attenuate signals having a first frequency between a first terminal and a second terminal of the power combiner/divider. The power combiner/divider also includes a second resonant circuit configured to attenuate signals having a second frequency between the first terminal and the second terminal, the bandwidth comprising the first frequency and the second frequency.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a schematic diagram of a first power combiner/divider of the transmitter of FIG. 3 and/or the receiver of the FIG. 4 including a number of inductors, according to embodiments of the present disclosure;

FIG. 6 is a layout diagram of the first power combiner/divider disposed on a first circuit layer and a second circuit layer, according to embodiments of the present disclosure;

FIG. 7 is a schematic diagram of a second power combiner/divider of the transmitter of FIG. 3 and/or the receiver of the FIG. 4 including coupled transmission lines, according to embodiments of the present disclosure;

FIG. 8 is a layout diagram of the second power combiner/divider, according to embodiments of the present disclosure; and

FIG. 9 is a plot diagram illustrating an attenuation response of the first power combiner/divider and/or the second power combiner/divider, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about.” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to a power combiner/divider with improved operating frequency range (e.g., bandwidth). The power combiner/divider may include an isolation circuit including a first resonant circuit and a second resonant circuit. The isolation circuit may improve isolation between multiple terminals of the power combiner/divider at a wider bandwidth compared to other power combiners/dividers without the isolation circuit, as will be appreciated.

In particular, the first resonant circuit and the second resonant circuit may be coupled to at least two terminals (e.g., input terminals, output terminals) of the power combiner/divider. The first resonant circuit may have a first resonant frequency. Moreover, the first resonant circuit may attenuate signals having frequencies in a first frequency range below an attenuation threshold (e.g., −3 decibels (dB), −10 dB, −20 dB, −22 dB, −25 dB, and so on). The first frequency range may include and/or may be based on the first resonant frequency. The attenuation threshold may correspond to an isolation value for reducing cross-talk or interference of transmission signals and/or received signals between the terminals of the power combiner/divider.

The second resonant circuit may have a second resonant frequency. Moreover, the second resonant circuit may attenuate signals having frequencies in a second frequency range below the attenuation threshold. The second frequency range may include and/or may be based on the second resonant frequency. In some embodiments, the first frequency range and the second frequency range may be adjacent and/or overlap. As such, the isolation circuit may reduce a leakage of signals having frequencies in the wider bandwidth between the terminals of the power combiner/divider. Accordingly, the power combiner/divider may receive input signals and/or generate output signals having frequencies in the wider bandwidth that is improved (e.g., widened) compared to a bandwidth of other power combiners/dividers.

With the foregoing in mind, the electronic device may include multiple data communication chains (e.g., transmitter chains, receiver chains) each being coupled to or otherwise including one or more power combiners/dividers. Each data communication chain may be coupled to one or more antennas of the electronic device to transmit and/or receive signals. In some embodiments, a bandwidth of each of the data communication chains for transmitting and/or receiving the signals may correspond to a portion of a device bandwidth of the electronic device.

Moreover, as discussed above, the power combiner/divider including the isolation circuit may have the wider bandwidth compared to other power combiners/dividers without the isolation circuit. As such, a bandwidth of each of the data communication chains including the power combiner/divider may correspond to an increased portion of the device bandwidth of the electronic device compared to other data communication chains. Accordingly, the electronic device may include a reduced number of data communication chains and/or power combiners/dividers to transmit and/or receive the signals with a frequency in the device bandwidth. The data communication chains may occupy a reduced circuit area based on including the reduced number of data communication chains and/or power combiners/dividers.

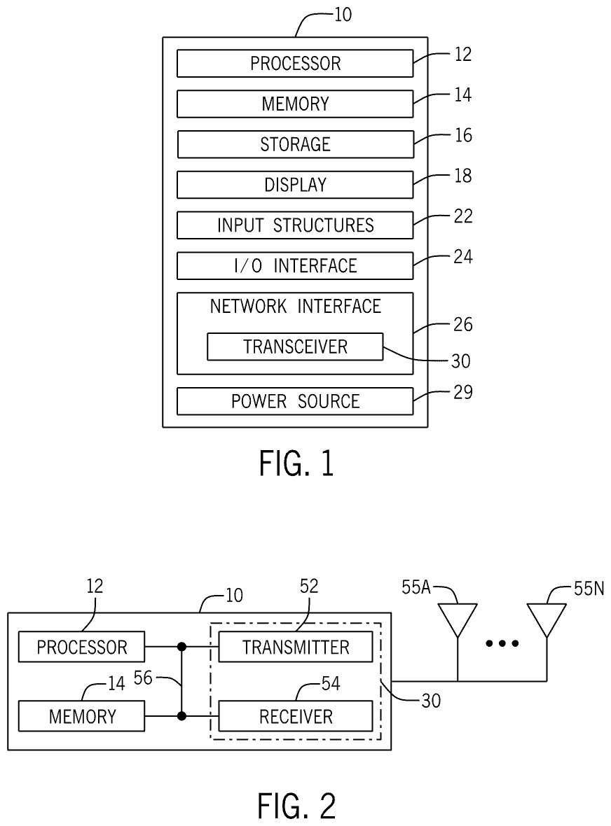

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. The power source 29 may provide input power to one or more components of the electronic device 10. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, Long Term Evolution® (LTE) cellular network, Long Term Evolution License Assisted Access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of electrical power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as the antennas 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. In some embodiments, the transmitter 52 may include one or more transmitter chains including various circuit components to generate transmitted signals. Moreover, the receiver 54 may include one or more receiver chains including various circuit components to generate transmitted signals, as will be appreciated.

The electronic device 10 may also have the antennas 55 electrically coupled to the transceiver 30. The antennas 55 may be configured in an omnidirectional or directional configuration, in a single-beam, dual-beam, or multi-beam arrangement, and so on. One or more of the antennas 55 may be associated with one or more beams, a frequency bandwidth, and various configurations. In some embodiments, multiple antennas of the antennas 55 of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

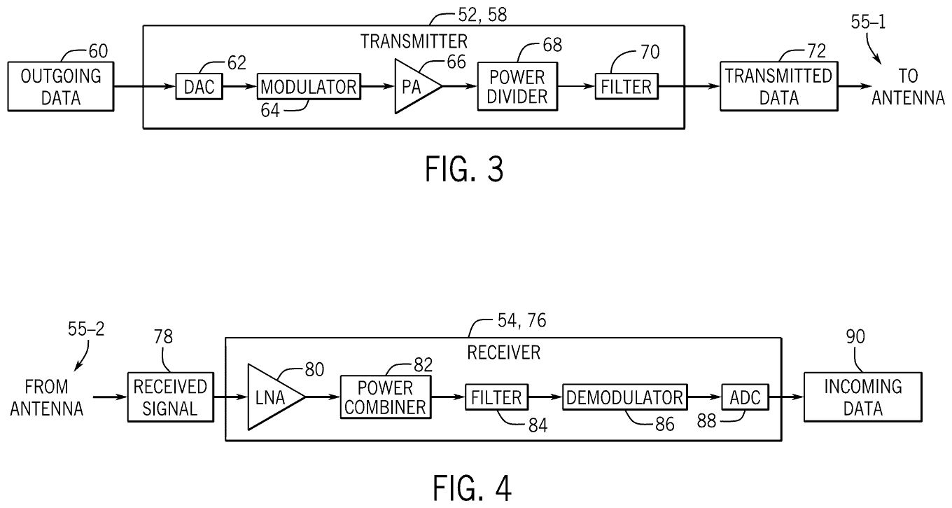

FIG. 3 is a schematic diagram of a portion of the transmitter 52 including a transmitter chain 58, according to embodiments of the present disclosure. In some embodiments, the electronic device 10 discussed above may include the transmitter 52 and the transmitter chain 58. The transmitter chain 58 may couple to a first antenna group 55-1 of the antennas 55 to transmit transmitted signals 72. In different embodiments, the first antenna group 55-1 may include a different number of antennas 55. The transmitter chain 58 may generate the transmitted signals 72 for transmission by the first antenna group 55-1 based on receiving outgoing data 60. The processor 12 of the electronic device 10 discussed above and/or any other viable circuit may generate and/or provide the outgoing data 60.

As illustrated, the transmitter chain 58 may receive outgoing data 60 in the form of digital signals to be transmitted via the first antenna group 55-1. A digital-to-analog converter (DAC) 62 of the transmitter chain 58 may convert the digital signals to analog signals. A modulator 64 may combine the analog signals with carrier signals to generate radio waves. A power amplifier (PA) 66 receives the modulated signals from the modulator 64. The power amplifier 66 may amplify the modulated signals to a suitable level to drive transmission of the signals via the first antenna group 55-1. frequency

A power divider or splitter 68 may divide the amplified signals to first divided signals and second divided signals. The first divided signals may include a first portion of the amplified signals and the second divided signals may include a second portion (e.g., a remaining portion) of the amplified signals. In some embodiments, the transmitter chain 58 may transmit the first divided signals and the second divided signals via the first antenna group 55-1. In alternative or additional embodiments, a second transmitter chain of the transmitter 52 (not shown for simplicity) may transmit the second divided signals via a respective antenna group (e.g., a different antenna group, the first antenna group 55-1). The second transmitter chain may include similar or different circuitry compared to the transmitter chain 58. Moreover, it should be appreciated that although the power divider 68 is disposed between the modulator 64 and a filter 70, in other embodiments, the power divider 68 may be disposed between the DAC 62 and the modulator 64, between the modulator 64 and the PA 66, or any other viable location.

The filter 70 (e.g., filter circuitry and/or software) of the transmitter chain 58 may then remove undesirable noise from the amplified signals (e.g., the first divided signals, the second divided signals, or both). As such, the filter 70 may generate the transmitted signals 72 to be transmitted via the first antenna group 55-1. The filter 70 may include any suitable filter or filters to remove the undesirable noise from the amplified signals, such as a bandpass filter, a bandstop filter, a low pass filter, a high pass filter, and/or a decimation filter.

The DAC 62, the modulator 64, the power amplifier 66, the power divider 68, and/or the filter 70 may be referred to as part of a radio frequency front end (RFFE), and more specifically, a transmit front end (TXFE) of the electronic device 10. Additionally, the transmitter chain 58 may include any suitable additional components not shown, or may not include certain of the illustrated components, such that the transmitter chain 58 may transmit the outgoing data 60 via the first antenna group 55-1. For example, the transmitter chain 58 may include a mixer and/or a digital up converter. As another example, the transmitter chain 58 may not include the filter 70 if the power amplifier 66 outputs the amplified signals in or approximately in a desired frequency range (e.g., such that filtering of the amplified signals may be unnecessary).

FIG. 4 is a schematic diagram of a portion of the receiver 54 including a receiver chain 76, according to embodiments of the present disclosure. In some embodiments, the electronic device 10 discussed above may include the receiver 54 and the receiver chain 76. The receiver chain 76 may couple to a second antenna group 55-2 of the antennas 55 to receive received signals 78. In different embodiments, the second antenna group 55-2 may include a different number of antennas 55. The receiver chain 76 may generate incoming data 90 based on receiving the received signals 78 from the second antenna group 55-2.

As illustrated, the receiver chain 76 may receive the received signals 78 from the second antenna group 55-2 in the form of analog signals. A low noise amplifier (LNA) 80 may amplify the received analog signals to a first suitable level for the receiver chain 76 to generate first amplified signals. A power combiner 82 may receive the first amplified signals and second amplified signals. The power combiner 82 may combine the first amplified signals and the second amplified signals to generate combined signals. As such, the combined signals may include the first amplified signals and the second amplified signals.

In some embodiments, the receiver chain 76 may receive the first amplified signals and the second amplified signals via the second antenna group 55-2. For example, the low noise amplifier 80 may amplify the received analog signals to a second suitable level for the receiver chain 76 to generate the second amplified signals. In alternative or additional embodiments, a second receiver chain of the receiver 54 (not shown for simplicity) may generate the second amplified signals based on receiving respective received signals via a respective antenna group. For example, the second receiver chain may generate the second amplified signals based on receiving at least a portion the received signals 78 via the second antenna group 55-2 and/or a different antenna group of the antennas 55. The second receiver chain may include similar or different circuitry compared to the receiver chain 54. It should be appreciated that although the power combiner 82 is disposed between the low noise amplifier 80 and a filter 84, in other embodiments, the power combiner 82 may be disposed between the filter 84 and a demodulator 86, between the demodulator 86 and an analog-to-digital converter (ADC) 88, or any other viable location.

The filter 84 (e.g., filter circuitry and/or software) may remove undesired noise from the combined signals, such as cross-channel interference. The filter 84 may also remove additional signals received by the one or more antennas 55 that are at frequencies other than the desired signals. The filter 84 may include any suitable filter or filters to remove the undesired noise or signals from the received signals, such as a bandpass filter, a bandstop filter, a low pass filter, a high pass filter, and/or a decimation filter. The low noise amplifier 80 and/or the filter 84 may be referred to as part of the RFFE, and more specifically, a receiver front end (RXFE) of the electronic device 10.

The demodulator 86 may remove a radio frequency carrier signal and/or extract a demodulated signal (e.g., an envelope signal) from the filtered signals for processing. The analog-to-digital converter 88 may receive the demodulated analog signals and convert the signals to digital signals of the incoming data 90 to be further processed by the electronic device 10. For example, the processor 12 and/or any other viable circuit of the electronic device 10 discussed above may receive and/or process the incoming data 90. Additionally, the receiver chain 76 may include any suitable additional components not shown, or may not include certain of the illustrated components, such that the receiver chain 76 may receive the received signals 78 via the second antenna group 55-2. For example, the receiver chain 76 may include a mixer and/or a digital down converter.

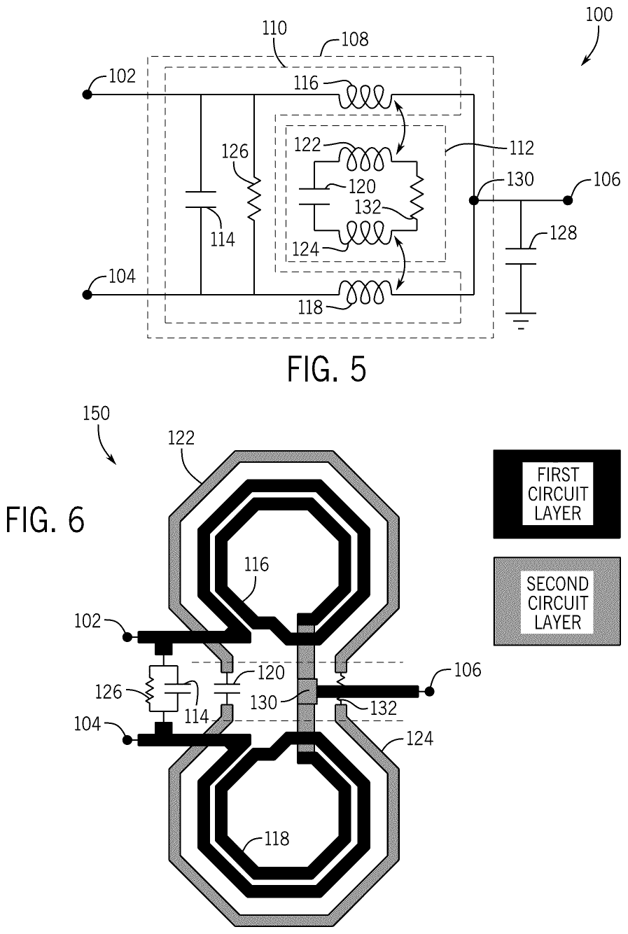

FIG. 5 is a schematic diagram of a first power combiner/divider 100, according to embodiments of the present disclosure. The first power combiner/divider 100 may include a first terminal 102, a second terminal 104, and a third terminal 106. The first power combiner/divider 100 may also include a first isolation circuit 108 including a first resonant circuit 110 and a second resonant circuit 112. The first resonant circuit 110 and the second resonant circuit 112 are coupled to and/or disposed between the first terminal 102 and the second terminal 104 of the first power combiner/divider 100, as will be appreciated. In some embodiments, the electronic device 10, the transmitter 52, and/or the receiver 54 discussed above may include the first power combiner/divider 100.

In specific embodiments, the power divider 68 of the transmitter chain 58 discussed above with respect to FIG. 3 may include the first power combiner/divider 100. As such, the third terminal 106 may operate as an input terminal and the first terminal 102 and the second terminal 104 may operate as output terminals of the first power combiner/divider 100. Moreover, the first power combiner/divider 100 may generate first output signals and second output signals based on receiving input signals. For example, the first power combiner/divider 100 may generate the first divided signals and the second divided signals based on receiving the amplified signals. The first power combiner/divider 100 may receive the input signals (e.g., the amplified signal) via the third terminal 106, output the first output signals (e.g., the first divided signals) via the first terminal 102, and output the second divided signals (e.g., the second divided signals) via the second terminal 104.

In alternative or additional embodiments, the power combiner 82 of the receiver chain 82 discussed above with respect to FIG. 4 may include the first power combiner/divider 100. As such, the first terminal 102 and the second terminal 104 may operate as input terminals and the third terminal may operate as an output terminal of the first power combiner/divider 100. Moreover, the first power combiner/divider 100 may generate output signals based on receiving first input signals and second input signals. For example, the first power combiner/divider 100 may generate the combined signals based on receiving the first amplified signals and the second amplified signals. The first power combiner/divider 100 may receive the first input signals (e.g., the first amplified signals) via the first terminal 102, receive the second input signals (e.g., the second amplified signals) via the second terminal 104, and output the output signals (e.g., the combined signals) via the third terminal 106. It should be appreciated that the power combiner 82 and/or the power divider 68 may reduce cross-talks and/or leakage signals between the first terminal 102 and the second terminal 104 when receiving the input signals in odd mode (e.g., differential mode) based on including the first power combiner/divider 100.

With the foregoing in mind, the first power combiner/divider 100 may include a first capacitor 114, a first inductor 116, a second inductor 118, a second capacitor 120, a third inductor 122, a fourth inductor 124, a first resistor 126, and a shunt capacitor 128. The first capacitor 114, the first resistor 126, the first inductor 116, and the second inductor 118 may form the first resonant circuit 110. The first capacitor 114 may be coupled to the first terminal 102 and second terminal 104. The first capacitor 114 may provide a path with an impedance lower than a threshold (e.g., lower than 10 ohms (Ω), lower than 500Ω, lower than 200Ω, and so on) between the first terminal 102 and the second terminal 104.

The first resistor 126 may be coupled to the first terminal 102 and the second terminal 104. The first resistor 126 and the first capacitor 114 may be coupled in parallel. The first resistor 126 may provide a path with an impedance higher than a threshold (e.g., higher than 100Ω, higher than 500Ω, higher than 200Ω, and so on) between the first terminal 102 and the second terminal 104. The first inductor 116 may be coupled to the first terminal 102, the first capacitor 114, and the first resistor 126, and may be coupled to the third terminal 106, the second inductor 118, and the shunt capacitor 128 via a first node 130. The second inductor 118 may be coupled to the second terminal 104, the first resistor 126, and the first capacitor 114, and may be coupled to the third terminal 106, the first inductor 116, and the shunt capacitor 128 via the first node 130.

The first resistor 126, the first capacitor 114, the first inductor 116, and the second inductor 118 may form a first loop having a first resonant frequency. The first resonant circuit 110 may provide high impedance to signals having frequencies in a first frequency range between the first terminal 102 and the second terminal 104. The first frequency range may include the first resonant frequency. The first resonant circuit 110 may attenuate signals having frequencies in the first frequency range below an attenuation threshold (e.g., −3 dB, −10 dB, −20 dB, −22 dB, −25 dB, and so on) between the first terminal 102 and the second terminal 104. The attenuation threshold may correspond to an isolation value for reducing cross-talk or interference of the signals between the first terminal 102 and the second terminal 104. Accordingly, the first resonant circuit 110 may reduce cross-talk or interference of signals having frequencies in the first frequency range between the first terminal 102 and the second terminal 104. That is, the first resonant circuit 110 may attenuate leakage signals between the first terminal 102 and the second terminal 104. Accordingly, the first power combiner/divider 100 may receive input signals and/or generate output signals having frequencies in the first frequency range.

In some embodiments, adjusting a resistance value of the first resistor 126 may adjust (e.g., shift) the first resonant frequency, the first frequency range, and/or the attenuation of the signals (e.g., the leakage signals) having frequencies in the first frequency range. As such, a resistance value of the first resistor 126 may be selected based on a desired resonant frequency, a desired frequency range for attenuating the leakage signals, and/or a desired attenuation (e.g., attenuation threshold) of the leakage signals. It should be appreciated that the resistance value of the first resistor 126 may be selected during manufacturing and/or after manufacturing during normal operation, for example, based on having a tunable first resistor 126.

As mentioned above, the first power combiner/divider 100 may also include the second capacitor 120, the third inductor 122, the fourth inductor 124, and the second resistor 132. The second capacitor 120, the second resistor 132, the third inductor 122, and the fourth inductor 124 may form the second resonant circuit 112. The third inductor 122 may be coupled to the second capacitor 120 and the second resistor 132. Moreover, the third inductor 122 may be disposed in proximity of the first inductor 116 such that the third inductor 122 and the first inductor 116 may inductively or magnetically couple during operation of the first power combiner/divider 100. The fourth inductor 124 may also be coupled to the second capacitor 120 and the second resistor 132. Moreover, the fourth inductor 124 may be disposed in proximity of the second inductor 118 such that the fourth inductor 124 and the second inductor 118 may inductively or magnetically couple during operation of the first power combiner/divider 100.

The second capacitor 120, the second resistor 132, the third inductor 122, and the fourth inductor 124 may form a second loop having a second resonant frequency. In different embodiments, the second loop may be disposed within or around the first loop discussed above. The second resonant circuit 112 may provide high impedance to signals having frequencies in a second frequency range between the first terminal 102 and the second terminal 104. The second frequency range may include the second resonant frequency. The second resonant circuit 112 may attenuate signals having frequencies in the second frequency range below the attenuation threshold between the first terminal 102 and the second terminal 104. Accordingly, the second resonant circuit 112 may reduce cross-talk or interference of signals having frequencies in the second frequency range between the first terminal 102 and the second terminal 104. That is, the second resonant circuit 112 may attenuate leakage signals between the first terminal 102 and the second terminal 104. Accordingly, the first power combiner/divider 100 may receive input signals and/or generate output signals having frequencies in the second frequency range.

In some embodiments, a resistance value between the third inductor 122 and the fourth inductor 124 may be adjusted based on a desired second resonant frequency, a desired second frequency range for attenuating the leakage signals, and/or a desired attenuation (e.g., attenuation threshold) of the leakage signals. The resistance value between the third inductor 122 and the fourth inductor 124 may correspond to a value of the second resonant frequency, the second frequency range, and/or the attenuation of the signals (e.g., the leakage signals) having frequencies in the second frequency range. For example, adjusting the resistance value between the third inductor 122 and the fourth inductor 124 may include adjusting a resistance value of the second resistor 132, selecting a quality factor of the third inductor 122 and/or the fourth inductor 124 during manufacturing, among other things. In specific cases, the first power combiner/divider 100 may not include the second resistor 132. It should be appreciated that the resistance value of the second resistor 132 may be selected during manufacturing and/or after manufacturing during normal operation, for example, based on having a tunable second resistor 132.

As mentioned above, the first power combiner/divider 100 may also include the shunt capacitor 128. The shunt capacitor 128 is coupled to the third terminal 106 and coupled to the first inductor 116 and the second inductor 118 via the first node 130. For example, the shunt capacitor 128 may provide a low-impedance path for noise signals having a frequency outside the first frequency range and/or the second frequency range. Moreover, the first inductor 116, the second inductor 118, and the shunt capacitor 128 provide impedance matching and/or isolation between the first terminal 102, the second terminal 104, and the third terminal 106 to combine and/or divide the input signals.

As discussed above, the first resonant circuit 110 may reduce a leakage of signals having frequencies in the first frequency range and the second resonant circuit 112 may reduce a leakage of signals having frequencies in the second frequency range. As such, the first resonant circuit 110 and the second resonant circuit 112 may attenuate signals having frequencies in a widened bandwidth including the first frequency range and the second frequency range between the first terminal 102 and the second terminal 104. In some embodiments, the first frequency range and the second frequency range may be adjacent and/or may overlap. Accordingly, the first isolation circuit 108, including the first resonant circuit 110 and the second resonant circuit 112, may reduce a leakage of signals having frequencies in the widened bandwidth between the first terminal 102 and the second terminal 104. Accordingly, the first power combiner/divider 100 may receive input signals and/or generate output signals having frequencies in the widened bandwidth that is improved (e.g., widened) compared to a bandwidth of other power combiners/dividers.

FIG. 6 is a layout 150 diagram of the first power combiner/divider 100, according to embodiments of the present disclosure. The layout 150 may include the first resonant circuit 110 including the first capacitor 114, the first resistor 126, the first inductor 116, and the second inductor 118. Moreover, the layout 150 may include the second resonant circuit 112 including the second capacitor 120, the third inductor 122, the fourth inductor 124, and the second resistor 132 of the first power combiner/divider 100. It should be appreciated that in alternative or additional embodiments, the first inductor 116 and the second inductor 118 may have different shapes, forms, and/or proximity.

The first capacitor 114 and the first resistor 126 may be coupled to the first terminal 102 and the second terminal 104 in parallel. The first inductor 116 may be coupled to the first terminal 102, the first capacitor 114, and the first resistor 126, and may be coupled to the third terminal 106 and the second inductor 118 via the first node 130. The second inductor 118 may be coupled to the second terminal 104, the first capacitor 114, and the first resistor 126, and may be coupled to the third terminal 106 and the first inductor 116 via the first node 130.

The third inductor 122 may be coupled to the second capacitor 120 and the second resistor 132. Moreover, the third inductor 122 may be disposed in proximity of the first inductor 116. As such, the first inductor 116 and the third inductor 122 may inductively couple during operation of the first power combiner/divider 100.

In the depicted embodiment, the third inductor 122 may be disposed concentrically (e.g., approximately concentrically) around a structure of the first inductor 116. For example, the first inductor 116 and the third inductor 122 may share a same center. In alternative or additional embodiments, the third inductor 122 may be disposed concentrically (e.g., approximately concentrically) within a structure of the first inductor 116. In yet alternative or additional embodiments, the first inductor 116 and the third inductor 122 may be eccentric (e.g., not share a same center). For example, the first inductor 116 and the third inductor 122 may be interwoven or intertwined with one another. In yet alternative or additional embodiments, at least a portion of the first inductor 116 and the third inductor 122 may overlap.

Moreover, the fourth inductor 124 may be coupled to the second capacitor 120 and the second resistor 132. The fourth inductor 124 may be disposed in proximity of the second inductor 118. As such, the second inductor 118 and the fourth inductor 124 may inductively couple during operation of the first power combiner/divider 100.

The fourth inductor 124 may be disposed concentrically (e.g., approximately concentrically) around a structure of the second inductor 118. For example, the second inductor 118 and the fourth inductor 124 may share a same center. In alternative or additional embodiments, the fourth inductor 124 may be disposed concentrically (e.g., approximately concentrically) within a structure of the second inductor 118. In yet alternative or additional embodiments, the second inductor 118 and the fourth inductor 124 may be eccentric (e.g., not share a same center). For example, the second inductor 118 and the fourth inductor 124 may be interwoven or intertwined with one another. In yet alternative or additional embodiments, at least a portion of the second inductor 118 and the fourth inductor 124 may overlap.

In the depicted embodiment, the first inductor 116 and the second inductor 118 are disposed on a first circuit layer, for example, of a printed circuit board. Moreover, the third inductor 122 and the fourth inductor 124 are disposed on a second circuit layer, for example, of the printed circuit board. In some embodiments, the first resonant circuit 110 may be disposed on the first circuit layer and the second resonant circuit 112 may be disposed on the second circuit layer. In different embodiments, the first circuit layer may be disposed above or below the second circuit layer by different distances. For example, the first circuit layer and the second circuit layer may be distanced by a length (e.g., less than 1 nanometer (nm), less than 1 nm, less than 3 nm, less than 3.5 nm, greater than or equal to 3.5 nm, and so on). In some cases, the third inductor 122 and the first inductor 116 may inductively or magnetically couple during operation of the first power combiner/divider 100 based on a first coupling factor. The first coupling factor may correspond to the length of the distance, among other things. Similarly, the fourth inductor 124 and the second inductor 118 may inductively or magnetically couple during operation of the first power combiner/divider 100 based on a second coupling factor. The second coupling factor may correspond to the length of the distance, among other things. Moreover, it should be appreciated that in alternative or additional embodiments, different portions of the first inductor 116, the second inductor 118, the third inductor 122, and the fourth inductor 124 may be disposed on a same circuit layer or different circuit layers.

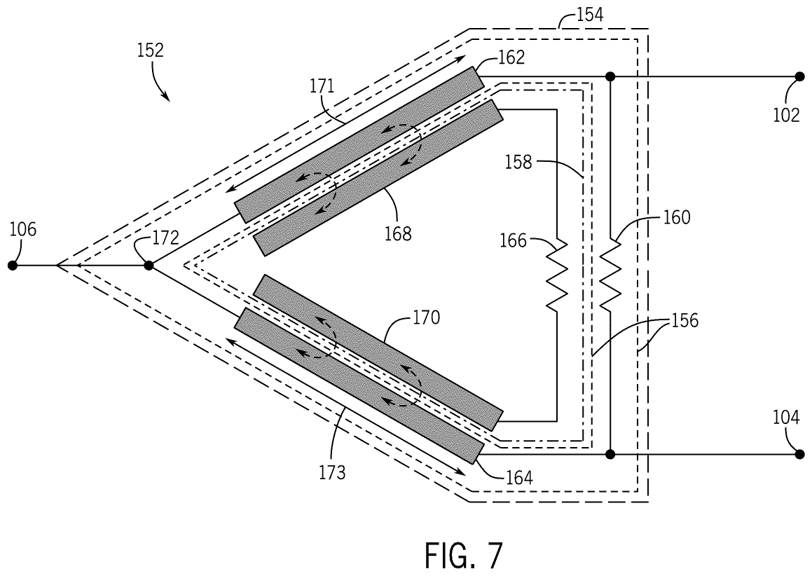

FIG. 7 is a schematic diagram of a second power combiner/divider 152, according to embodiments of the present disclosure. The second power combiner/divider 152 may include the first terminal 102, the second terminal 104, and the third terminal 106. The second power combiner/divider 152 may also include a second isolation circuit 154 including a third resonant circuit 156 and a fourth resonant circuit 158, as will be appreciated. The third resonant circuit 156 and the fourth resonant circuit 158 are coupled to and/or disposed between the first terminal 102 and the second terminal 104 of the second power combiner/divider 152. In some embodiments, the electronic device 10, the transmitter 52, and/or the receiver 54 discussed above may include the second power combiner/divider 152.

In specific embodiments, the power divider 68 of the transmitter chain 58 discussed above with respect to FIG. 3 may include the second power combiner/divider 152. As such, the third terminal 106 may operate as an input terminal and the first terminal 102 and the second terminal 104 may operate as output terminals of the second power combiner/divider 152. Moreover, the second power combiner/divider 152 may generate first output signals and second output signals based on receiving input signals. For example, the second power combiner/divider 152 may generate the first divided signals and the second divided signals based on receiving the amplified signals. The second power combiner/divider 152 may receive the input signals (e.g., the amplified signal) via the third terminal 106, output the first output signals (e.g., the first divided signals) via the first terminal 102, and output the second divided signals (e.g., the second divided signals) via the second terminal 104.

In alternative or additional embodiments, the power combiner 82 of the receiver chain 82 discussed above with respect to FIG. 4 may include the second power combiner/divider 152. As such, the first terminal 102 and the second terminal 104 may operate as input terminals and the third terminal may operate as an output terminal of the second power combiner/divider 152. Moreover, the second power combiner/divider 152 may generate output signals based on receiving first input signals and second input signals. For example, the second power combiner/divider 152 may generate the combined signals based on receiving the first amplified signals and the second amplified signals. The second power combiner/divider 152 may receive the first input signals (e.g., the first amplified signals) via the first terminal 102, receive the second input signals (e.g., the second amplified signals) via the second terminal 104, and output the output signals (e.g., the combined signals) via the third terminal 106.

With the foregoing in mind, the second power combiner/divider 152 may include a third resistor 160, a first transmission line 162, a second transmission line 164, a fourth resistor 166, a third transmission line 168, and a fourth transmission line 170. In some cases, the third resistor 160 may correspond to and/or include the first resistor 126 of the first power combiner/divider 100 discussed above. Moreover, in some cases, the fourth resistor 166 may correspond to and/or include the second resistor 132 of the first power combiner/divider 100 discussed above. In specific cases, the second power combiner/divider 152 may additionally include the shunt capacitor 128 (discussed above) coupled to the third terminal 106. It should be appreciated that the power combiner 82 and/or the power divider 68 may reduce cross-talks and/or leakage signals between the first terminal 102 and the second terminal 104 when receiving the input signals in odd mode (e.g., differential mode) based on including the second power combiner/divider 152.

The third resistor 160, the first transmission line 162, and the second transmission line 164 may form the third resonant circuit 156. The third resistor 160 may be coupled to the first terminal 102 and second terminal 104. The third resistor 160 may provide a path with an impedance higher than a threshold (e.g., higher than 100Ω, higher than 500Ω, higher than 200Ω, and so on) between the first terminal 102 and the second terminal 104. The first transmission line 162 may be coupled to the first terminal 102 and a first end of the third resistor 160, and may be coupled to the third terminal 106 and the second transmission line 164 via a second node 172. The second transmission line 164 may be coupled to the second terminal 104 and a second end of the third resistor 160.

The third resistor 160, the first transmission line 162, and the second transmission line 164 may form a third loop (e.g., a closed loop) having the first resonant frequency. The third resonant circuit 156 may provide high impedance to signals having frequencies in the first frequency range between the first terminal 102 and the second terminal 104. The first frequency range may include the first resonant frequency. In some cases, the third resonant circuit 156 may attenuate signals having frequencies in the first frequency range below an attenuation threshold (e.g., −3 dB, −10 dB, −20 dB, −22 dB, −25 dB, and so on) between the first terminal 102 and the second terminal 104.

As mentioned above, the attenuation threshold may correspond to an isolation value for reducing cross-talk or interference of the signals between the first terminal 102 and the second terminal 104. Accordingly, the third resonant circuit 156 may reduce cross-talk or interference of signals having frequencies in the first frequency range between the first terminal 102 and the second terminal 104. That is, the third resonant circuit 156 may attenuate leakage signals between the first terminal 102 and the second terminal 104. Accordingly, the second power combiner/divider 152 may receive input signals and/or generate output signals having frequencies in the first frequency range.

Although the first resonant frequency and the first frequency range are described with respect to the first resonant circuit 110 (discussed above with respect to FIGS. 5 and 6) and the third resonant circuit 156, in alternative or additional embodiments, the first resonant circuit 110 and/or the third resonant circuit 156 may have any other viable resonant frequency and/or frequency range. In the depicted embodiment, adjusting a resistance value of the third resistor 160 may adjust (e.g., shift) the first resonant frequency, the first frequency range, and/or the attenuation of the signals (e.g., the leakage signals) having frequencies in the first frequency range. As such, a resistance value of the third resistor 160 may be selected based on a desired resonant frequency, a desired frequency range for attenuating the leakage signals, and/or a desired attenuation (e.g., attenuation threshold) of the leakage signals. It should be appreciated that the resistance value of the first resistor 126 may be selected during manufacturing and/or after manufacturing during normal operation, for example, based on having a tunable first resistor 126.

As mentioned above, the second power combiner/divider 152 may also include the fourth resistor 166, the third transmission line 168, and the fourth transmission line 170. The fourth resistor 166, the third transmission line 168, and the fourth transmission line 170 may form the fourth resonant circuit 158. A first end of the third transmission line 168 may be coupled to a first end of the fourth resistor 166. Moreover, a first end of the fourth transmission line 170 may be coupled to a second end of the fourth resistor 166. In the depicted embodiment, a second end of the third transmission line 168 and a second end of the fourth transmission line 170 may remain open (e.g., not connected). The fourth resistor 166, the third transmission line 168, and the fourth transmission line 170 may form a fourth loop (e.g., nearly a loop, an open loop) having the second resonant frequency. In different embodiments, the fourth loop may be disposed within or around the third loop discussed above.

The fourth resonant circuit 158 may provide high impedance to signals having frequencies in the second frequency range between the first terminal 102 and the second terminal 104. The second frequency range may include the second resonant frequency. Similarly, the fourth resonant circuit 158 may attenuate signals having frequencies in the second frequency range below the attenuation threshold between the first terminal 102 and the second terminal 104. As such, the fourth resonant circuit 158 may reduce cross-talk or interference of signals having frequencies in the second frequency range between the first terminal 102 and the second terminal 104. That is, the fourth resonant circuit 158 may attenuate leakage signals between the first terminal 102 and the second terminal 104. Accordingly, the second power combiner/divider 152 may receive input signals and/or generate output signals having frequencies in the second frequency range.

In particular, the third transmission line 168 may be disposed in proximity of the first transmission line 162 to form a first coupled transmission line (CTL). As such, the third transmission line 168 and the first transmission line 162 may inductively or magnetically couple during operation of the second power combiner/divider 152. For example, dimensions of (e.g., a length of), a spacing between, and/or a dielectric material between the first transmission line 162 and the third transmission line 168, among other things, may correspond to a third coupling factor between the first transmission line 162 and the third transmission line 168. Moreover, the desired coupling factor may be adjusted based on a desired resonant frequency (e.g., the first resonant frequency, the second resonant frequency), a desired frequency range for attenuating the leakage signals, and/or a desired attenuation (e.g., the attenuation threshold) of the leakage signals. In specific cases, the desired coupling factor may also be selected based on a desired impedance matching with one or more components coupled to the first terminal 102, the second terminal 104, and/or the third terminal 106.

In some embodiments, a length 171 of the first transmission line 162 may be selected based on a wavelength of the signals (e.g., the amplified signals, divided signals, combined signals, among other signals). For example, the length 171 of the first transmission line 162 may correspond to (e.g., may be equal to, may be nearly equal to) a portion of (e.g., a quarter of, two third of, half of, and so on) the wavelength of the signals. In some embodiments, the electronic device 10 may combine and/or divide signals using the second power combiner/divider 152 in odd mode and even mode. In specific embodiments, the length 171 of the first transmission line 162, the third transmission line 168, or both may correspond to (e.g., may be equal to, may be nearly equal to) a portion of (e.g., a quarter of, two third of, half of, and so on) an average of wavelengths of signals in the odd mode and signals in the even mode.

Moreover, the fourth transmission line 170 may be disposed in proximity of the second transmission line 164 to form a second coupled transmission line. As such, the fourth transmission line 170 and the second transmission line 164 may inductively or magnetically couple during operation of the second power combiner/divider 152. For example, a spacing between, a dielectric material between, and/or dimensions of (e.g., a length of) the second transmission line 164 and the fourth transmission line 170, among other things, may correspond to a fourth coupling factor between the second transmission line 164 and the fourth transmission line 170. In specific cases, the third coupling factor and the fourth coupling factor may be equal (e.g., nearly equal).

Moreover, the desired coupling factor may be adjusted based on the desired resonant frequency, a desired frequency range for attenuating the leakage signals, and/or a desired attenuation (e.g., the attenuation threshold) of the leakage signals. Similar to the first coupled transmission line, the desired coupling factor may also be selected based on a desired impedance matching with the one or more components coupled to the first terminal 102, the second terminal 104, and/or the third terminal 106.

In some embodiments, a length 173 of the second transmission line 164 may be selected based on a wavelength of the signals (e.g., the amplified signals, divided signals, combined signals, among other signals). For example, the length 173 of the second transmission line 164 may correspond to (e.g., may be equal to, may be nearly equal to) a portion of (e.g., a quarter of, two third of, half of, and so on) the wavelength of the signals. Moreover, a resistance value of the third resistor 160 may correspond to an impedance value of the first coupled transmission line and/or the second coupled transmission line. For example, the resistance value of the third resistor 160 may correspond to (e.g., may be equal to, may be nearly equal to) a multiple of or a summation of a resistance value of the first coupled transmission line and the second coupled transmission line.

Alternatively or additionally, the resistance value between the first coupled transmission line and the second coupled transmission line may be adjusted based on a desired resonant frequency, a desired frequency range for attenuating the leakage signals, and/or a desired attenuation (e.g., attenuation threshold) of the leakage signals. The resistance value may correspond to a value of the desired resonant frequency, the desired frequency range, and/or the attenuation of the signals (e.g., the leakage signals) having frequencies in the desired frequency range. For example, adjusting the resistance value between the first coupled transmission line and the second coupled transmission line may include adjusting a resistance value of the fourth resistor 166, selecting a dimensions, spacing, and/or material of the transmission lines 162, 164, 168, and/or 170, among other things. In specific cases, the second power combiner/divider 152 may not include the fourth resistor 166. It should be appreciated that the resistance value of the fourth resistor 166 may be selected during manufacturing and/or after manufacturing during normal operation, for example, based on having a tunable fourth resistor 166.

As discussed above, the third resonant circuit 156 may reduce a leakage of signals having frequencies in the first frequency range and the fourth resonant circuit 158 may reduce a leakage of signals having frequencies in the second frequency range. As such, the third resonant circuit 156 and the fourth resonant circuit 158 may attenuate signals having frequencies in a widened bandwidth including the first frequency range and the second frequency range between the first terminal 102 and the second terminal 104. In some embodiments, the first frequency range and the second frequency range may be adjacent and/or may overlap. Accordingly, the second isolation circuit 154, including the third resonant circuit 156 and the fourth resonant circuit 158, may reduce a leakage of signals having frequencies in the widened bandwidth between the first terminal 102 and the second terminal 104. Accordingly, the second power combiner/divider 152 may receive input signals and/or generate output signals having frequencies in the widened bandwidth that is improved (e.g., widened) compared to a bandwidth of other power combiners/dividers.

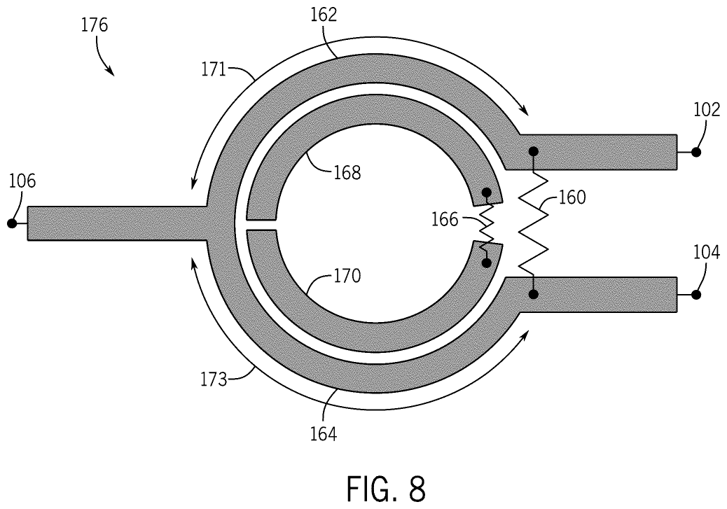

FIG. 8 is a layout 176 diagram of the second power combiner/divider 152, according to embodiments of the present disclosure. The layout 150 may include the third resonant circuit 156 including the third resistor 160, the first transmission line 162, and the second transmission line 164. Moreover, the layout 150 may include the fourth resonant circuit 158 including the fourth resistor 166, the third transmission line 168, and the fourth transmission line 170. It should be appreciated that in alternative or additional embodiments, the transmission lines 162, 164, 168, and/or 170 may each have different shapes, forms, and/or proximity.

The third resistor 160 may be coupled to the first terminal 102 and the second terminal 104. The first transmission line 162 may be coupled to the first terminal 102 and the third resistor 160, and may be coupled to the third terminal 106 and the second transmission line 164 via the second node 172. The second transmission line 164 may be coupled to the second terminal 104 and the third resistor 160, and may be coupled to the third terminal 106 and the first transmission line 162 via the second node 172.

The third transmission line 168 may be coupled to the fourth resistor 166. Moreover, the third transmission line 168 may be disposed in proximity of the first transmission line 162. As such, the first transmission line 162 and the third transmission line 168 may inductively/capacitively couple during operation of the second power combiner/divider 152. Moreover, as discussed above, the first transmission line 162 may have a length 171 and the second transmission line 164 may have a length 173.

In the depicted embodiment, the third transmission line 168 may be disposed concentrically (e.g., approximately concentrically) around a structure of the first transmission line 162. For example, the first transmission line 162 and the third transmission line 168 may share a same center. In alternative or additional embodiments, the third transmission line 168 may be disposed concentrically (e.g., approximately concentrically) within a structure of the first transmission line 162. In yet alternative or additional embodiments, the first transmission line 162 and the third transmission line 168 may be eccentric (e.g., not share a same center). For example, the first transmission line 162 and the third transmission line 168 may be interwoven or intertwined with one another. In yet alternative or additional embodiments, at least a portion of the first transmission line 162 and the third transmission line 168 may overlap.

Moreover, the fourth transmission line 170 may be coupled to the fourth resistor 166. The fourth transmission line 170 may be disposed in proximity of the second transmission line 164. As such, the second transmission line 164 and the fourth transmission line 170 may inductively/capacitively couple during operation of the second power combiner/divider 152.

The fourth transmission line 170 may be disposed concentrically (e.g., approximately concentrically) around a structure of the second transmission line 164. For example, the second transmission line 164 and the fourth transmission line 170 may share a same center. In alternative or additional embodiments, the fourth transmission line 170 may be disposed concentrically (e.g., approximately concentrically) within a structure of the second transmission line 164. In yet alternative or additional embodiments, the second transmission line 164 and the fourth transmission line 170 may be eccentric (e.g., not share a same center). For example, the second transmission line 164 and the fourth transmission line 170 may be interwoven or intertwined with one another. In yet alternative or additional embodiments, at least a portion of the second transmission line 164 and the fourth transmission line 170 may overlap.

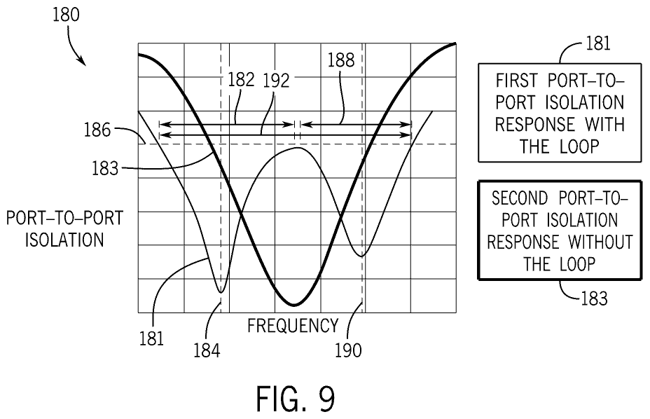

FIG. 9 is a plot diagram 180 illustrating a first port-to-port isolation response 181 of the first power combiner/divider 100 and/or the second power combiner/divider 152, according to embodiments of the present disclosure. In some embodiments, the first port-to-port isolation response 181 may be associated with the first power combiner/divider 100 having the second resonant circuit 112 (e.g., the second loop disposed within or around the first loop discussed above). In alternative or additional embodiments, the first port-to-port isolation response 181 may be associated with the second power combiner/divider 152 having the fourth resonant circuit 158 (e.g., fourth loop disposed within or around the third loop discussed above). In any case, a second port-to-port isolation response 183 of the first power combiner/divider 100 and/or the second power combiner/divider 152 is shown without the second resonant circuit 112 (e.g., the second loop) and/or the fourth resonant circuit 158 (e.g., fourth loop) respectively for reference.

In the depicted embodiment, the first resonant circuit 110 and/or the third resonant circuit 156 may attenuate signals having frequencies in a first frequency range 182 including a first resonant frequency 184. In particular, the first resonant circuit 110 and/or the third resonant circuit 156 may attenuate signals having frequencies in the first frequency range 182 below an attenuation threshold 186 (e.g., −3 dB, −10 dB, −20 dB, −22 dB, −25 dB, and so on). As mentioned above, the first resonant circuit 110 and/or the third resonant circuit 156 may attenuate signals having frequencies in the first frequency range 182 between the first terminal 102 and the second terminal 104 (e.g., port-to-port isolation) of the first power combiner/divider 100 and/or the second power combiner/divider 152. It should be appreciated that although the first frequency range 182 and the first resonant frequency 184 are described as an example with respect to the first resonant circuit 110 and the third resonant circuit 156, in different embodiments, the first resonant circuit 110 or the third resonant circuit 156 may have different desired frequency range and/or different desired resonant frequency.

Moreover, the second resonant circuit 112 and/or the fourth resonant circuit 158 may attenuate signals having frequencies in a second frequency range 188 including a second resonant frequency 190. In particular, the second resonant circuit 112 and/or the fourth resonant circuit 158 may attenuate signals having frequencies in the second frequency range 188 below the attenuation threshold 186. As mentioned above, the second resonant circuit 112 and/or the fourth resonant circuit 158 may attenuate signals having frequencies in the second frequency range 188 between the first terminal 102 and the second terminal 104 of the first power combiner/divider 100 and/or the second power combiner/divider 152.

The first resonant circuit 110 and/or the third resonant circuit 156 may be tuned to have a first impedance response and the second resonant circuit 112 and/or the fourth resonant circuit 158 may be tuned to have a second impedance response corresponding to the second frequency range 188 and the first frequency range 182, respectively. Furthermore, it should be appreciated that although the second frequency range 188 and the second resonant frequency 190 are described as an example with respect to the second resonant circuit 112 and the fourth resonant circuit 158, in different embodiments, the second resonant circuit 112 or the fourth resonant circuit 158 may have different desired frequency range and/or different desired resonant frequency. In this manner, the first power combiner/divider 100 and/or the second power combiner/divider 152 may provide the first port-to-port isolation response 181. Moreover, the first power combiner/divider 100 and/or the second power combiner/divider 152 may provide the second port-to-port isolation response 183 without the second resonant circuit 112 (e.g., the second loop) and/or the fourth resonant circuit 158 (e.g., fourth loop) respectively for reference.

The attenuation threshold 186 may correspond to an isolation value for reducing cross-talk or interference of the signals between the first terminal 102 and the second terminal 104 (e.g., a broadband port-to-port isolation threshold). Accordingly, the first resonant circuit 110 and/or the third resonant circuit 156 may reduce cross-talk or interference of signals having frequencies in the first frequency range 182 between the first terminal 102 and the second terminal 104. Moreover, the second resonant circuit 112 and/or the fourth resonant circuit 158 may reduce cross-talk or interference of signals having frequencies in the second frequency range 188 between the first terminal 102 and the second terminal 104.

As discussed above, the first isolation circuit 108 may include the first resonant circuit 110 and the second resonant circuit 112. As such, the first isolation circuit 108 and/or the second isolation circuit 154 may attenuate signals having frequencies in a bandwidth 192 (e.g., the widened bandwidth discussed above) including the first frequency range 182 and the second frequency range 188 between the first terminal 102 and the second terminal 104. That is, the bandwidth 192 may correspond to a broadband port-to-port isolation bandwidth between the first terminal 102 and the second terminal 104. For example, the first frequency range 182 and the second frequency range 188 may be adjacent and/or may overlap. In specific cases, the first power combiner/divider 100 and/or the second power combiner/divider 152 may have an improved insertion loss between the first terminal 102 and the third terminal 106 and/or between the second terminal 104 and the third terminal 106 based on including the first isolation circuit 108 and the second isolation circuit 154 compared to other power combiners/dividers. Accordingly, the first power combiner/divider 100 and/or the second power combiner/divider 152 may receive input signals and/or generate output signals having frequencies in the widened bandwidth that is improved (e.g., widened) compared to a bandwidth of other power combiners/dividers.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

In an embodiment, a power combiner/divider may include a first resistor, a first transmission line coupled to the first resistor, a second transmission line coupled to the first resistor and the first transmission line forming a closed loop, a third transmission line, a fourth transmission line, and a second resistor coupled to the third transmission line and the fourth transmission line forming an open loop. The open loop may be disposed within or around the closed loop.

The power combiner/divider may include a shunt capacitor coupled to the first transmission line and the second transmission line.

The third transmission line may inductively couple to the first transmission line and the fourth transmission line may inductively couple to the second transmission line.

The first resistor, the first transmission line, and the second transmission line may attenuate a first signal having a first frequency in a first frequency range between a first terminal and a second terminal of the power combiner/divider.

The first resistor, the first transmission line, and the second transmission line may have a first resonant frequency. The first frequency range may be associated with the first resonant frequency.

The third transmission line, the fourth transmission line, and the second resistor may attenuate a second signal having a second frequency in a second frequency range between the first terminal and the second terminal.

The first frequency range and the second frequency range may be adjacent or overlapping.

The power combiner/divider may receive a first input signal by a first terminal, receive a second input signal by a second terminal, and output a combined signal by a third terminal of the power combiner/divider.

The power combiner/divider may receive a first input signal by a third terminal of the power combiner/divider, output a first output signal by a first terminal, and output a second output signal by a second terminal.

In an alternative or additional embodiment, a power combiner/divider may include a first resonant circuit that may attenuate a first signal received between a first terminal and a second terminal. The first resonant circuit may include a first transmission line coupled to the first terminal and a third terminal and a second transmission line coupled to the second terminal and the third terminal. The power combiner/divider may also include a second resonant circuit that may attenuate a second signal received between the first terminal and the second terminal. The second resonant circuit may include a third transmission line that may inductively couple to the first transmission line and a fourth transmission line that may inductively couple to the second transmission line.

The first resonant circuit may include a resistor coupled to the first terminal, the first transmission line, the second terminal, and the second transmission line.

The first transmission line may be coupled to a first end of the resistor and the second transmission line may be coupled to a second end of the resistor.

The second resonant circuit may include a resistor coupled to the third transmission line and the fourth transmission line.

The third transmission line may be coupled to a first end of the resistor and the fourth transmission line may be coupled to a second end of the resistor.

In yet another alternative or additional embodiment, an electronic device may include one or more antennas and a power combiner/divider coupled to the one or more antennas. The power combiner/divider may include a first resonant circuit including a first transmission line coupled to a first terminal and a second transmission line coupled to a second terminal. The power combiner/divider may also include a second resonant circuit including a third transmission line and a fourth transmission line. The third transmission line may inductively couple to the first transmission line. The fourth transmission line may be coupled to the third transmission line and may inductively couple to the second transmission line.

The first resonant circuit may include a resistor coupled to the first terminal, the first transmission line, the second terminal, and the second transmission line.

The first transmission line may be coupled to a first end of the resistor and the second transmission line may be coupled to a second end of the resistor.

The second resonant circuit may include a resistor, a first end of the resistor being may be coupled to the fourth transmission line and a second end of the resistor may be coupled to the third transmission line.

The power combiner/divider may to receive signals from or provide the signals to the one or more antennas. The first resonant circuit may attenuate a first signal received between the first terminal and the second terminal of the power combiner/divider. The second resonant circuit may attenuate a second signal received between the first terminal and the second terminal.

The first resonant circuit may have a first resonant frequency associated with a first frequency range. The first signal may have a first frequency in the first frequency range. The second resonant circuit may have a second resonant frequency associated with a second frequency range. The second signal may have a second frequency in the second frequency range.

1. A power combiner/divider comprising:
a first capacitor;
a first resistor coupled in parallel to the first capacitor;
a first inductor coupled to the first capacitor and the first resistor;
a second inductor coupled to the first capacitor, the first resistor, and the first inductor forming a first loop;
a second capacitor;
a third inductor coupled to the second capacitor; and
a fourth inductor coupled to the second capacitor and the third inductor forming a second loop, the second loop being disposed within or around the first loop.

2. The power combiner/divider of claim 1, comprising a second resistor coupled to the third inductor and the fourth inductor, wherein the third inductor is coupled to the fourth inductor via the second resistor.

3. The power combiner/divider of claim 1, wherein the third inductor is configured to inductively couple to the first inductor and the fourth inductor is configured to inductively couple to the second inductor.

4. The power combiner/divider of claim 1, wherein the first capacitor, the first resistor, the first inductor, and the second inductor are configured to attenuate signals having a frequency in a first frequency range between a first terminal and a second terminal of the power combiner/divider.

5. The power combiner/divider of claim 4, wherein the first capacitor, the first resistor, the first inductor, and the second inductor have a first resonant frequency, the first frequency range being associated with the first resonant frequency.

6. The power combiner/divider of claim 4, wherein the second capacitor, the third inductor, and the fourth inductor are configured to attenuate signals having a frequency in a second frequency range between the first terminal and the second terminal, the first frequency range and the second frequency range being adjacent or overlapping.

7. The power combiner/divider of claim 6, wherein the power combiner/divider is configured to receive a first input signal by the first terminal, receive a second input signal by the second terminal, and output a combined signal by a third terminal of the power combiner/divider, the first input signal, the second input signal, and the combined signal having frequencies in the first frequency range or the second frequency range.

8. The power combiner/divider of claim 6, wherein the power combiner/divider is configured to receive a first input signal by a third terminal of the power combiner/divider, output a first output signal by the first terminal, and output a second output signal by the second terminal, the first input signal, the first output signal, and the second output signal having frequencies in the first frequency range or the second frequency range.

9. The power combiner/divider of claim 1, wherein the power combiner/divider is disposed on a printed circuit board, the first inductor and the second inductor being disposed on a first circuit layer of the printed circuit board, and the third inductor and the fourth inductor being disposed on a second circuit layer of the printed circuit board.

10. A power combiner/divider comprising:
a first resonant circuit configured to attenuate signals having a frequency in a first frequency range between a first terminal and a second terminal, the first resonant circuit comprising a first inductor coupled to the first terminal and a third terminal and a second inductor coupled to the second terminal and the third terminal; and
a second resonant circuit configured to attenuate signals having a frequency in a second frequency range between the first terminal and the second terminal, the second resonant circuit comprising a third inductor configured to inductively couple to the first inductor and a fourth inductor configured to inductively couple to the second inductor.

11. The power combiner/divider of claim 10, wherein the first inductor and the second inductor are disposed on a first circuit layer and the third inductor and the fourth inductor are disposed on a second circuit layer.

12. The power combiner/divider of claim 11, comprising a distance between the first circuit layer and the second circuit layer, the third inductor being configured to inductively couple to the first inductor and the fourth inductor being configured to inductively couple to the second inductor based on the distance.

13. The power combiner/divider of claim 12, wherein the second resonant circuit comprises
a first capacitor coupled to the first terminal, the second terminal, and the first inductor, and
a first resistor coupled to the first terminal, the second terminal, and the first inductor.

14. The power combiner/divider of claim 13, wherein the second resonant circuit comprises
a second capacitor coupled to the third inductor and the fourth inductor, and
a second resistor coupled to the third inductor and the fourth inductor, the third inductor being coupled to the fourth inductor via the second resistor.

15. An electronic device comprising:
one or more antennas; and
a power combiner/divider coupled to the one or more antennas, the power combiner/divider configured to receive signals from or provide the signals to the one or more antennas having a frequency in a bandwidth, the power combiner/divider comprising
a first resonant circuit configured to attenuate signals having a first frequency between a first terminal and a second terminal of the power combiner/divider, and
a second resonant circuit configured to attenuate signals having a second frequency between the first terminal and the second terminal, the bandwidth comprising the first frequency and the second frequency.

16. The electronic device of claim 15, wherein the first frequency is in a first frequency range and the second frequency is in a second frequency range, the bandwidth comprising the first frequency range and the second frequency range.

17. The electronic device of claim 16, wherein the first resonant circuit has a first resonant frequency, the first frequency range being associated with the first resonant frequency, and wherein the second resonant circuit has a second resonant frequency, the second frequency range being associated with the second resonant frequency.

18. The electronic device of claim 15, wherein the first resonant circuit comprises a first capacitor coupled to the first terminal and the second terminal, a first resistor coupled to the first terminal and the second terminal, a first inductor coupled to the first terminal and a third terminal, and a second inductor coupled to the first terminal and the third terminal.

19. The electronic device of claim 18, wherein the second resonant circuit comprises a second capacitor coupled to a third inductor and a fourth inductor, the third inductor coupled to the second capacitor and the fourth inductor, the third inductor being configured to inductively couple to the first inductor, and the fourth inductor being configured to inductively couple to the second inductor.

20. The electronic device of claim 15, wherein the first resonant circuit comprises a first resistor coupled to the first terminal and the second terminal, a first transmission line coupled to the first terminal and a third terminal, and a second transmission line coupled to the first terminal and the third terminal, and wherein the second resonant circuit comprises a second resistor coupled to a third transmission line and a fourth transmission line, the third transmission line coupled to the second resistor and the fourth transmission line, the third transmission line being configured to inductively couple to the first transmission line, and the fourth transmission line being configured to inductively couple to the second transmission line.
